(19) United States
(12) Patent Application Publication
(10) Pub. No.: US 2021/0184077 A1
(43) Pub. Date: Jun. 17, 2021

(54) LIGHT-EMITTING DEVICE

(71) Applicant: InnoLux Corporation, Miao-Li County (TW)

(72) Inventors: Shun-Yuan HU, Miao-Li County (TW); Li-Wei MAO, Miao-Li County (TW); Ker-Yih KAO, Miao-Li County (TW)

(21) Appl. No.: 17/097,045

(22) Filed: Nov. 13, 2020

(30) Foreign Application Priority Data
Dec. 12, 2019 (CN) 201911273163.6

(51) Int. Cl. H01L 33/20; H01L 33/62; H01L 33/52

(52) U.S. Cl. CPC H01L 33/20; H01L 33/52; H01L 33/62

(57) ABSTRACT

An optical element driving system is provided. The optical element driving system includes an optical element driving mechanism and a control assembly. The optical element driving mechanism includes a movable portion, a fixed portion, a driving assembly, and a position sensing assembly. The movable portion connects to an optical element. The movable portion is movable relative to the fixed portion. The movable portion is in an accommodating space in the fixed portion. The driving assembly is used for driving the movable portion to move relative to the fixed portion. The control assembly provides a driving signal to the driving assembly to control the driving assembly. The position sensing assembly is used for detecting the movement of the movable portion relation to the fixed portion and providing a motion sensing signal to the control assembly.

### CROSS REFERENCE TO RELATED APPLICATIONS

This application claims the benefit of China Patent Application No. 201911273163.6, filed on Dec. 12, 2019, the entirety of which is incorporated by reference herein.

### BACKGROUND OF THE DISCLOSURE

### Field of the Disclosure

The present disclosure relates to a light-emitting device.

### Description of the Related Art

Electronic products have become indispensable necessities in modern society. With the vigorous development of such electronic products, consumers have high expectations on the quality, function and price of these products.

Some electronic products have light-emitting or display functions, but light-emitting devices have not yet met requirements in all respects.

### BRIEF SUMMARY OF DISCLOSURE

A light-emitting device is provided in some embodiments of the present disclosure. The light-emitting device includes a flexible substrate, a light-emitting unit, a thin film transistor, and a circuit. The flexible substrate has a via. The light-emitting unit is disposed on a top surface of the flexible substrate. The thin film transistor is electrically connected to the light-emitting unit. The circuit is disposed on the bottom surface of the flexible substrate and transmitting a signal for driving the light-emitting unit through the via

### BRIEF DESCRIPTION OF DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1A is a schematic view of a light-emitting device in some embodiments of the present disclosure.

FIG. 1B is an enlarged view of the light-emitting device in FIG. 1A.

FIG. 2 is a schematic view of a light-emitting device in some embodiments of the present disclosure.

FIG. 3A and FIG. 3B are schematic views of some light-emitting devices in some embodiments of the present disclosure.

FIG. 4 is a schematic view of a light-emitting device in some embodiments of the present disclosure.

FIG. 5 is a schematic view of a light-emitting device in some embodiments of the present disclosure.

FIG. 6 is a schematic view of a light-emitting device in some embodiments of the present disclosure.

FIG. 7A to FIG. 7H are schematic views of a method of forming a light-emitting device in some embodiments of the present disclosure.

FIG. 8A to FIG. 8G are schematic views of a method of forming a light-emitting device in some embodiments of the present disclosure.

FIG. 9A is a top view of a light-emitting device in some embodiments of the present disclosure.

FIG. 9B is a cross-sectional view of the light-emitting device in FIG. 9A illustrated along a line B-B′.

### DETAILED DESCRIPTION OF DISCLOSURE

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are in direct contact, and may also include embodiments in which additional features may be disposed between the first and second features, such that the first and second features may not be in direct contact.

In addition, the present disclosure may repeat reference numerals and/or letters in the various examples. This repetition is for the purpose of simplicity and clarity and does not in itself dictate a relationship between the various embodiments and/or configurations discussed. Moreover, the formation of a feature on, connected to, and/or coupled to another feature in the present disclosure that follows may include embodiments in which the features are in direct contact, and may also include embodiments in which additional features may be disposed interposing the features, such that the features may not be in direct contact. In addition, spatially relative terms, for example, “vertical,” “on,” “over,” “below,”, “bottom,” etc. as well as derivatives thereof (e.g., “downwardly,” “upwardly,” etc.) are used in the present disclosure for ease of description of one feature's relationship to another feature. The spatially relative terms are intended to cover different orientations of the device, including the features.

Unless defined otherwise, all technical and scientific terms used herein have the same meaning as commonly understood by one of ordinary skill in the art to which this disclosure belongs. It should be appreciated that each term, which is defined in a commonly used dictionary, should be interpreted as having a meaning conforming to the relative skills and the background or the context of the present disclosure, and should not be interpreted in an idealized or overly formal manner unless defined otherwise.

The terms “about” and “substantially” typically mean+/−20%, +/−10%, +/−5%, +/−3%, +/−2%, +/−1%, or +/−0.5% of the stated value. The stated value of the present disclosure is an approximate value. When there is no specific description, the stated value includes the meaning of “about” or “substantially”.

In addition, in some embodiments of the present disclosure, terms concerning attachments, coupling and the like, such as “connected” and “interconnected”, refer to a relationship wherein structures are secured or attached to one another either directly or indirectly through intervening structures, as well as both movable or rigid attachments or relationships, unless expressly described otherwise. Moreover, in some embodiments, the terms may include two elements are electrically connected to each other or the two elements are not in direct contact with each other.

Furthermore, the phrase “in a range between a first value and a second value” or “in a range from a first value to a second value” indicates that the range includes the first value, the second value, and other values between them.

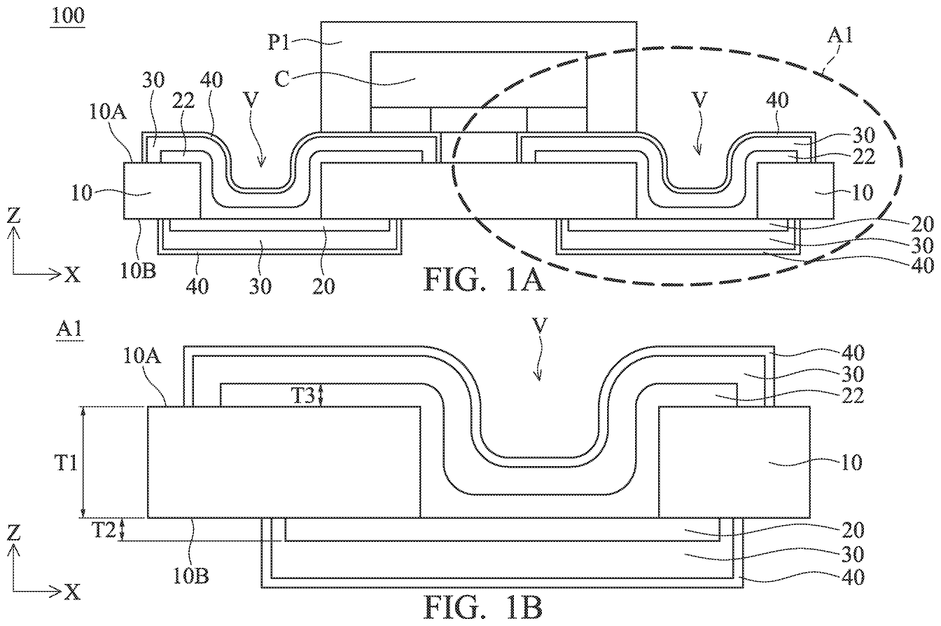

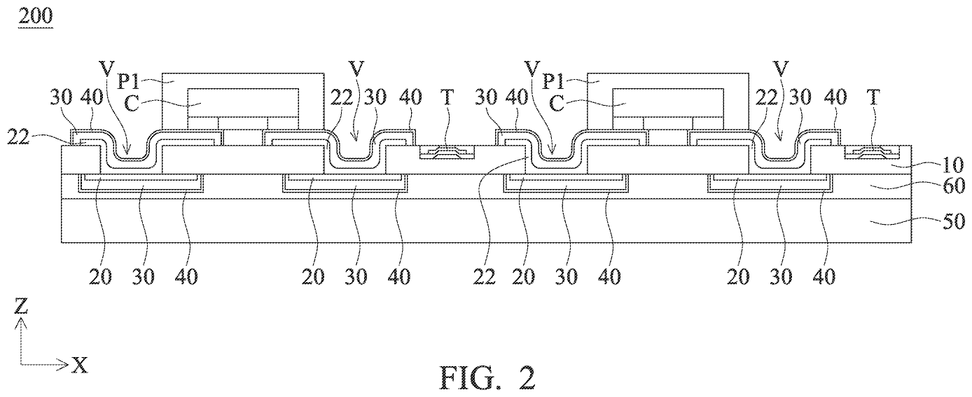

FIG. 1A is a schematic view of a light-emitting device 100 in some embodiments of the present disclosure, and FIG. 1B is an enlarged view of a portion A1 of the light-emitting device 100 in FIG. 1A. The light-emitting device 100 may include a flexible substrate 10, a conductive layer 20, a conductive layer 22, a barrier layer 30, a protective layer 40, and a light-emitting unit C, but not limited thereto. In FIG. 1B, the flexible substrate 10 may include vias V, and may include a top surface 10A and a bottom surface 10B. The conductive layer 20 may be disposed on the bottom surface 10B of the flexible substrate 10. The conductive layer 22 may be disposed on the top surface 10A of the flexible substrate 10 and in the vias V. In some embodiments, the conductive layer 22 may cover the sidewalls of the vias V and the conductive layer 20. The conductive layer 22 may directly or indirectly contact the sidewalls of the vias V and/or the conductive layer 20, but not limited thereto. The barrier layer 30 may be disposed on the conductive layer 20 and the conductive layer 22. The protective layer 40 may be disposed on the barrier layer 30. The light-emitting unit C may be disposed on the top surface 10A of the flexible substrate 10, and the protective layer 40 may be disposed between the light-emitting unit C and the barrier layer 30. In some embodiments, the light-emitting unit C may be electrically connected to the conductive layer 20 through the protective layer 40 and the barrier layer 30. In other embodiments, reaction may occur when the protective layer 40 is connected to the light-emitting unit C to allow the light-emitting unit C in direct contact with the barrier layer 30 (not shown), but it is not limited thereto.

In some embodiments, the flexible substrate 10 may include a base and/or circuits disposed in the base. The base may include polymer material, such as polycarbonate (PC), polyimide (PI), polypropylene (PP), polyethylene terephthalate (PET), another suitable material, or a combination thereof, but the present disclosure is not limited thereto. The circuit in the base may include passive matrix (PM) circuit, active matrix (AM) circuit, etc. For example, the flexible substrate 10 may be multi-layered, but not limited thereto.

In some embodiments, the material of the conductive layer 20 and/or the conductive layer 22 may include conductive material, such as Cu, Ag, Al, Au, Mo, Ti, W, Sn, Ni, another suitable material or a combination thereof, but the present disclosure is not limited thereto. The material of the barrier layer 30 may include metal (such as Ni, Pt, Ag, Au, Cu, or an alloy thereof), another suitable material, or a combination thereof, but the present disclosure is not limited thereto. In an embodiment, the conductive layer 20, the conductive layer 22, the barrier layer 30, and the protective layer 40 may include substantially identical material(s). In this embodiment, the barrier layer 30 and the protective layer 40 may be considered as an identical layer to the conductive layer 20 and/or the conductive layer 22, but the present disclosure is not limited thereto.

The conductive layer 20 and the conductive layer 22 may be located at opposite sides of the flexible substrate 10, and electric signals may be transmitted through both sides of the flexible substrate 10. The barrier layer 30 may be used for protecting the conductive layer 20 and/or the conductive layer 22, for example, the barrier layer 30 may reduce the chances of the material of the conductive layer 20 and/or the conductive layer 22 diffusing to other elements and resulting in the change of the resistance. The protective layer 40 may protect the conductive layer 20, the conductive layer 22, and/or the barrier layer 30 from being reacted to external environment (e.g. oxidation).

In the normal direction of the flexible substrate 10 (e.g. the Z direction), the thickness T2 of the conductive layer 20 or the thickness T3 of the conductive layer 22 may be less than the thickness T1 of the flexible substrate 10. The thickness T2 of the conductive layer 20 may be the maximum thickness of the conductive layer 20 on the bottom surface of the flexible substrate 10. The thickness T3 of the conductive layer 22 may be the thickness of the conductive layer 22 at the center region of the via V or the thickness of the conductive layer 22 on the top surface 10A, but not limited thereo. For example, in some embodiments, the thickness T1 of the flexible substrate 10 may be less than or equal to about 150 μm, such as 120 μm, 100 μm, 80 μm, 50 μm, or 30 μm, but it is not limited thereto. The thickness T2 of the conductive layer 20 or the thickness T3 of the conductive layer 22 may be less than or equal to about 100 μm, such as 80 μm, 60 μm, 50 μm, 30 μm, or 10 μm. Furthermore, in some embodiments, the thickness T2 of the conductive layer 20 may be substantially identical to the thickness T3 of the conductive layer 22, but it is not limited thereto. By making the thickness T1 of the flexible substrate 10 less than about 150 μm, or making the thickness T2 of the conductive layer 20 or the thickness T3 of the conductive layer T3 less than about 100 μm, the size of the light-emitting device 100 may be reduced to achieve miniaturization.

In some embodiments, the light-emitting unit C may include, for example, light-emitting diode (LED), other suitable elements or a combination thereof, but it is not limited thereto. The light-emitting diode may include inorganic light-emitting diode, organic light-emitting diode (OLED), mini LED, micro LED, quantum dot (QD), quantum dot light-emitting diode (QLED/QDLED), fluorescence material, phosphor material, another suitable material, or a combination thereof, but it is not limited thereto. In some embodiments, a package structure P1 may be disposed on the light-emitting unit C to protect the light-emitting unit C. In some embodiments, the material of the package structure P1 may include organic polymer, inorganic polymer, glass, or a combination thereof, but it is not limited thereto. In some embodiments, the package structure P1 may be transparent or translucent to allow the light emitted from the light-emitting unit C passing through, but it is not limited thereto.

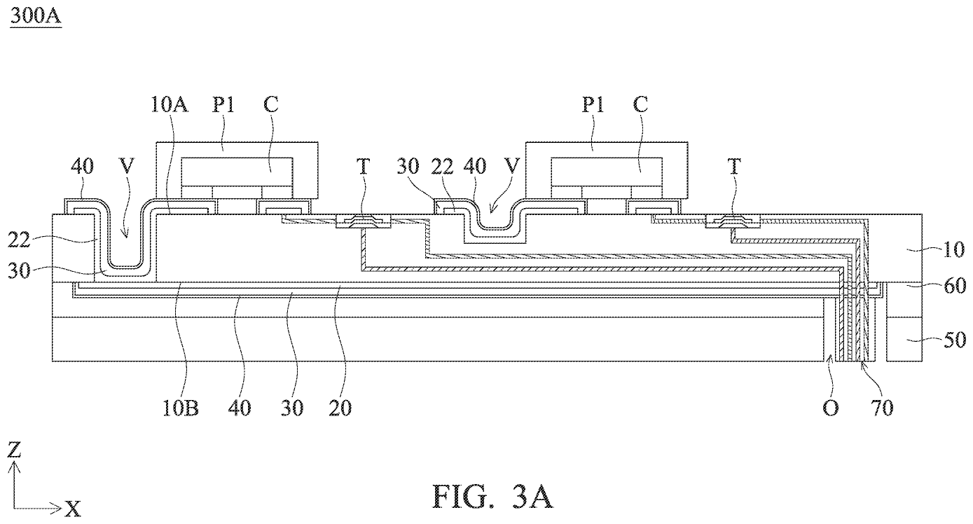

FIG. 2 is a schematic view of a light-emitting device 200 in some embodiments of the present disclosure. The flexible substrate 10 of the light-emitting device 200 may include at least one thin-film transistor (TFT) T, for example, the at least one thin-film transistor T may be disposed on the base (not shown) to drive other elements (such as the light-emitting unit C), but it is not limited thereto. In some embodiments, the thin-film transistor T may include a top gate thin-film transistor, a bottom gate thin-film transistor, a double gate thin-film transistor and/or a dual gate thin-film transistor, or a combination thereof, but it is not limited thereto. In some embodiments, the thin-film transistor T may include semiconductor materials, such as amorphous silicon, polysilicon (such as low temperature polysilicon (LTPS)), semiconductor oxide (such as indium gallium zinc oxide (IGZO)), other metal oxide, another suitable material, or a combination thereof, but it is not limited thereto. In some embodiments, different thin-film transistors T may include different semiconductor materials, but it is not limited thereto. For example, a thin-film transistor T may include low temperature polysilicon, and another thin-film transistor T may include semiconductor oxide, but it is not limited thereto.

Moreover, the light-emitting device 200 may further include a supporting layer 50 and a connecting layer 60 disposed between the flexible substrate 10 and the supporting layer 50. The supporting layer 50 may be disposed on one side of the flexible substrate 10 that is away from the light-emitting unit C. In other words, the flexible substrate 10 may be disposed between the supporting layer 50 and the light-emitting unit C. The material of the supporting layer 50 may include glass, aluminum, or another suitable material, but it is not limited thereto. In an embodiment, the supporting layer 50 may include a circuit board, but it is not limited thereto. In some embodiments, the hardness of the supporting layer 50 may be greater than the hardness of the flexible substrate 10 to enhance the strength of the light-emitting device 200. The material of the connecting layer 60 may include epoxy glue, silicon glue, photoresist, other suitable adhesives, or a combination thereof, but it is not limited thereto. The connecting layer 60 may be used for connecting the flexible substrate 10 and the supporting layer 50. Moreover, in some embodiments, the connecting layer 60 may be used to reduce the chance of corrosion or oxidation of the conductive layer 20, the barrier layer 30, or the protective layer 40 caused by exposure to the external environment, thereby protecting the conductive layer 20, the barrier layer 30, or the protective layer 40. In some embodiments, after the light-emitting device 200 having the supporting layer 50 is formed, the supporting layer 50 and the connecting layer 60 may be replaced by suitable flexible materials, such as polyimide, a flexible circuit board, or polyethylene terephthalate (PET), to achieve a light-emitting device having a flexible substrate, but it is not limited thereto.

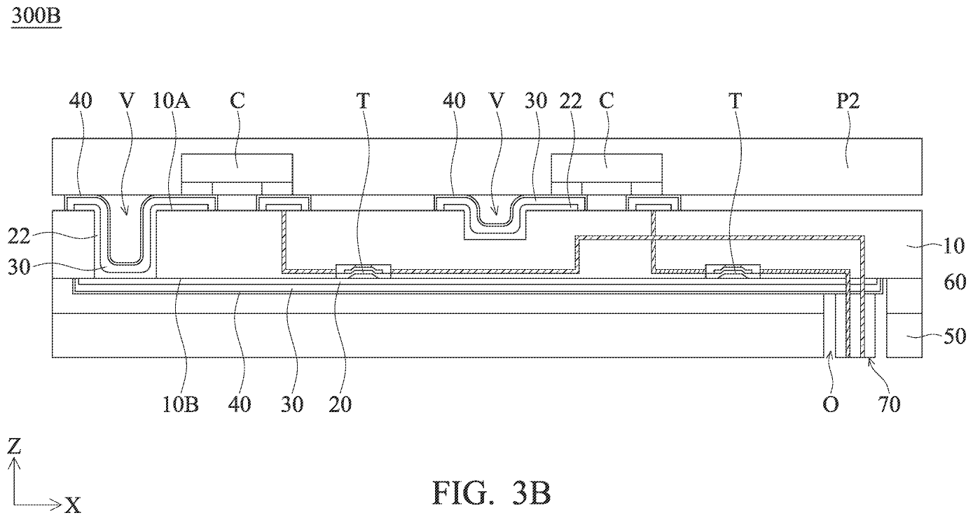

FIG. 3A and FIG. 3B are schematic views of a light-emitting device 300A and a light-emitting device 300B, respectively, in some embodiments of the present disclosure. In the light-emitting device 300A, the thin-film transistors T and the light-emitting units C may be disposed on the same side of the base (not shown), and may be electrically connected to other elements via the circuit disposed on another side of the base to allow the thin-film transistors T to receive the signal. In the light-emitting device 300B, the thin-film transistors T and the light-emitting units C may be disposed on opposite sides of the base (not shown) to meet different processing needs or design requirements. It should be noted that some circuits connected to the thin-film transistors T are omitted in FIG. 3B for simplicity.

In some embodiments, at least one opening O may be formed in the supporting layer 50 and/or the connecting layer 60, and various elements may be disposed on the side of the flexible substrate 10 that no light-emitting unit is disposed thereon. In some embodiments, the opening O may completely or partially penetrate the connecting layer 60. For example, as shown in FIG. 3A and FIG. 3B, an electronic element 70 may be disposed in the opening O, i.e. disposed adjacent to the bottom surface 10B of the flexible substrate 10. In some embodiments, the electronic element 70 may include a connector, a semiconductor chip, other suitable electronic elements, or a combination thereof. In other embodiments, as shown in FIG. 3B, the thin-film transistors T and the light-emitting units C may be disposed on opposite sides of the base, and the space on the top surface 10A of the flexible substrate 10 for disposing the light-emitting units C may be increased. The electronic element 70 may provide electrical connection for the light-emitting units C or the thin-film transistors T to the external environment through the circuit and the vias V, for example, the electronic element 70 may be used to transmit a signal for driving the light-emitting units C and/or the thin-film transistors T. Furthermore, the conductive layer 20, the barrier layer 30, or the protective layer 40 may also be electrically connected to external environment through the electronic element 70, but it is not limited thereto. In an embodiment, the semiconductor chip may be used to control the elements in the light-emitting device 300A or the light-emitting device 300B, such as the light-emitting units C, the thin-film transistors T, etc. The size of the light-emitting device 300A or the light-emitting device 300B may be reduced by disposing the semiconductor chip in the opening O. In some embodiments, the thickness of the semiconductor chip may be less than the sum of the thicknesses of the supporting layer 50 and the connecting layer 60 in the normal direction of the flexible substrate 10 (Z direction), and the semiconductor chip may be protected in the opening O, but it is not limited thereto. In other embodiments, the thickness of the semiconductor chip may be greater than the sum of the thicknesses of the supporting layer 50 and the connecting layer 60. In some embodiments, both of the connector and the semiconductor chip may be disposed in the light-emitting device, depending on design requirements.

In some embodiments, as shown in FIG. 3B, more than one light-emitting units C may be packaged in a single package structure P2 to simplify the process. Although the light-emitting units C and the thin-film transistor T in FIG. 3A are disposed on the same side of the base and the light-emitting units C are respectively packaged by different package structures P1 in FIG. 3A, the light-emitting units C and the thin-film transistor T in FIG. 3B are disposed on opposite sides of the base and the light-emitting units C are packaged by a single package structure P2 in FIG. 3B, the present disclosure is not limited thereto. For example, the present disclosure also includes embodiments that the light-emitting units C and the thin-film transistor T are disposed on the same side of the base, and the light-emitting units C are packaged by a single package structure P2, and embodiments that the light-emitting units C and the thin-film transistor T are disposed on opposite sides of the base, and the light-emitting units C are respectively packaged by different package structures P1, depending on design requirements.

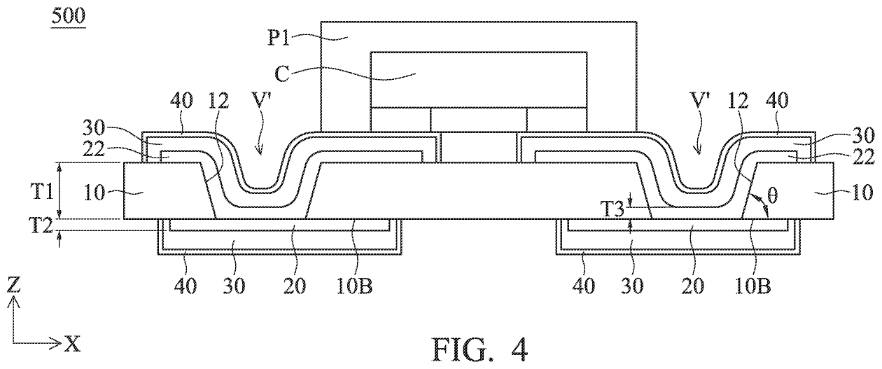

FIG. 4 is a schematic view of a light-emitting device 500 in some embodiments of the present disclosure. The light-emitting device 500 is substantially identical to the light-emitting device 100, and the difference is that vias V′ of the light-emitting device 500 have tapered (or inclined) sidewalls, and other similar structures are not repeated herein. The included angle θ between the sidewall 12 of the via V′ and the bottom surface 10B of the flexible substrate 10 may be between 30 degrees and 120 degrees (30 degrees≤angle θ≤120 degrees), such as 50 degrees, 60 degrees, 70 degrees, 90 degrees, 100 degrees, or 110 degrees, but not limited thereto. Therefore, the conductive layer 20 may be able to form a contact with the conductive layer 22 more easily, or the conductive layer 22 may be harder to break.

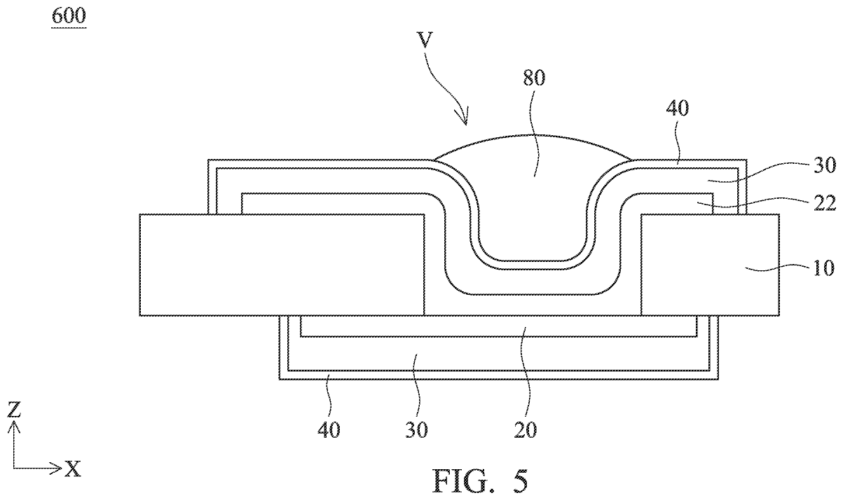

FIG. 5 is an enlarged view of a light-emitting device 600 in some embodiments of the present disclosure. It should be noted that the aforementioned light-emitting units C are not shown in the light-emitting device 600 for simplicity. After the conductive layer 22, the barrier layer 30, and the protective layer 40, etc. are disposed in the via V of the flexible substrate 10, a bonding material 80 may be additionally disposed in the via V. The bonding material 80 may include silver paste, copper paste, nano-metal powder, solder, another suitable material, or a combination thereof, but it is not limited thereto. The bonding material 80 may be used for electrically connecting conductive structures (such as the conductive layer 22, the barrier layer 30, the protective layer 40) and other elements (e.g. the light-emitting unit C), but it is not limited thereto. In an embodiment, because the bonding material 80 may be filled in the space of the via V, the mechanical strength of the via V of the light-emitting device 600 in the duration of the manufacturing process(es) may be enhanced, but it is not limited thereto.

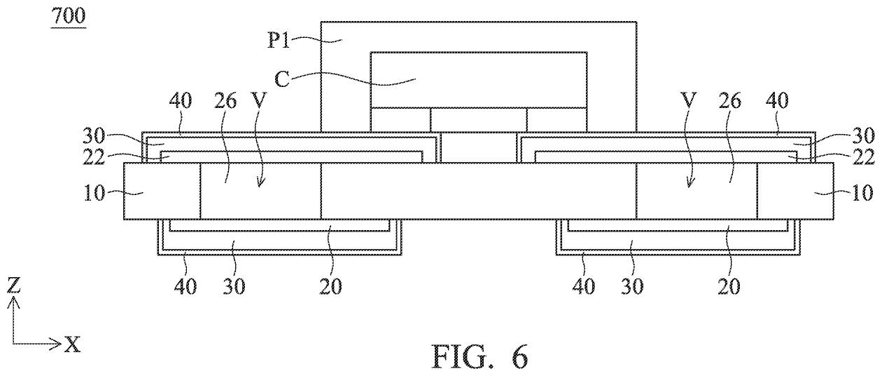

FIG. 6 is a schematic view of a light-emitting device 700 in some embodiments of the present disclosure. The difference between the light-emitting device 700 and the light-emitting devices in aforementioned embodiments is that conductive material 26 may be included in the vias V, and the conductive layer 22 may be electrically connected to the conductive layer 20 through the conductive material 26. The conductive material 26 may include metal (such as Cu, Ag, Au, Al, Ni, W, Sn or an alloy thereof), another suitable material, or a combination thereof, but it is not limited thereto. Therefore, the conductive layer 20 and the conductive layer 22 that are disposed on opposite sides of the flexible substrate 10 may be electrically connected to each other.

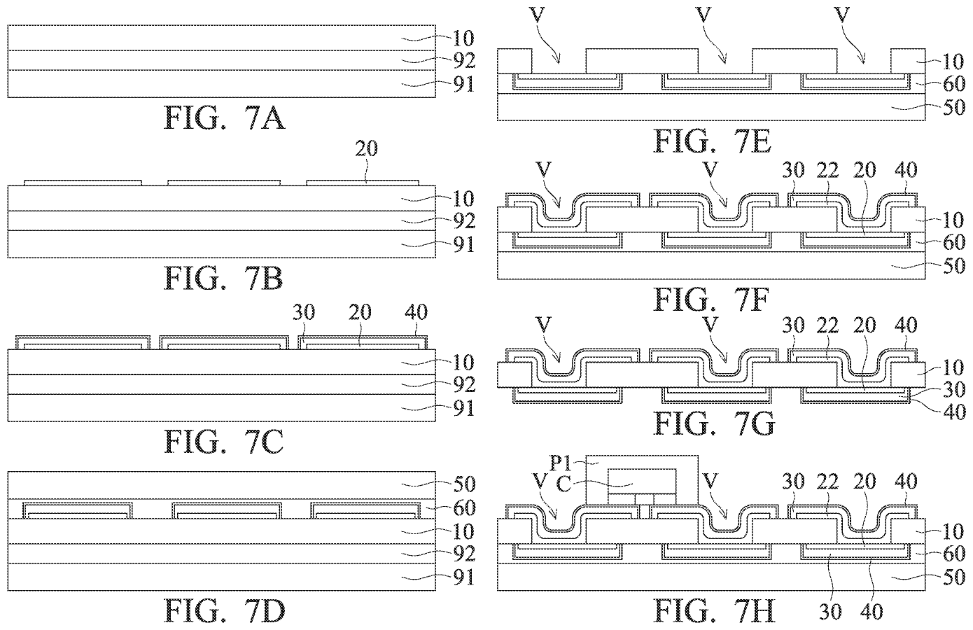

FIG. 7A to FIG. 7H are schematic views of a method for forming a light-emitting device (e.g. the light-emitting device 100) in some embodiments of the present disclosure. In FIG. 7A, a supporting substrate 91 is provided, and the flexible substrate 10 may be connected to the supporting substrate 91 through an adhesive layer 92. The flexible substrate 10 may include thin-film transistors. In other embodiments, a base (not shown) may be connected to the supporting substrate 91, and then forming a circuit layer or thin-film transistors (not shown) on the base to form the flexible substrate 10. The material of the supporting substrate 91 may include glass or another suitable material, but it is not limited thereto. The material of the adhesive layer 92 may include epoxy glue, silicon glue, photoresist, optical clear adhesive, optical clear resin, another suitable material, or a combination thereof, but it is not limited thereto. In some embodiments, the hardness of the supporting substrate 91 may be greater than the hardness of the flexible substrate 10 to support the flexible substrate 10 in subsequent processes. In some embodiments, the flexible substrate 10 may include the aforementioned thin-film transistors T. In an embodiment, the adhesive layer 92 may be not required, and the flexible substrate 10 may be formed on the supporting substrate 91 by coating to simplify the process. For example, the base of the flexible substrate 10 may be formed on the supporting substrate 91 by coating in the beginning, and then forms the circuit layer of the flexible substrate 10.

Afterwards, in FIG. 7B, the conductive layer 20 may be disposed on the flexible substrate 10, and the conductive layer 20 may be patterned. In some embodiments, the patterned conductive layer 20 may be disposed or formed by sputter, plating, photolithography, and/or printing, but it is not limited thereto.

In FIG. 7C, the barrier layer 30 and/or the protective layer 40 may be disposed on the conductive layer 20. The barrier layer 30 and/or the protective layer 40 may be disposed or formed by electroplating, chemical plating, etc., but it is not limited thereto. In FIG. 7D, the supporting layer 50 may be connected to the flexible substrate 10 through the connecting layer 60, and the connecting layer 60 may surround the conductive layer 20, the barrier layer 30, and the protective layer 40. Afterwards, in FIG. 7E, the whole structure may be flipped over, and the flexible substrate 10 is above the supporting layer 50. The supporting substrate 91 and the adhesive layer 92 may be removed by chemical etching, laser lift-off or mechanical peeling, and then the vias V may be formed in the flexible substrate 10 by laser and/or lithography, but it is not limited thereto. In FIG. 7F, the conductive layer 22, the barrier layer 30, and the protective layer 40 may be formed on the flexible substrate 10 and in the vias V. The conductive layer 22 may be formed by sputtering, electroplating, lithography, etc., and the barrier layer 30 and the protective layer 40 may be disposed or formed by electroplating, chemical plating, etc., but it is not limited thereto. In some embodiments, after the step in FIG. 7F, as shown in FIG. 7G, the supporting layer 50 and/or the connecting layer 60 may be removed. In some embodiments, after the step in FIG. 7F, as shown in FIG. 7H, the supporting layer 50 and/or the connecting layer 60 may remain. No matter the supporting layer 50 and the connecting layer 60 are removed or remain, the light-emitting unit C may be disposed on the flexible substrate 10 and electrically connected to other elements (not shown) on the flexible substrate 10 through the conductive layer 20, the conductive layer 22, the barrier layer 30, and the protective layer 40. However, the present disclosure is not limited thereto. A new supporting layer and/or a new connecting layer may be formed after the step in FIG. 7G.

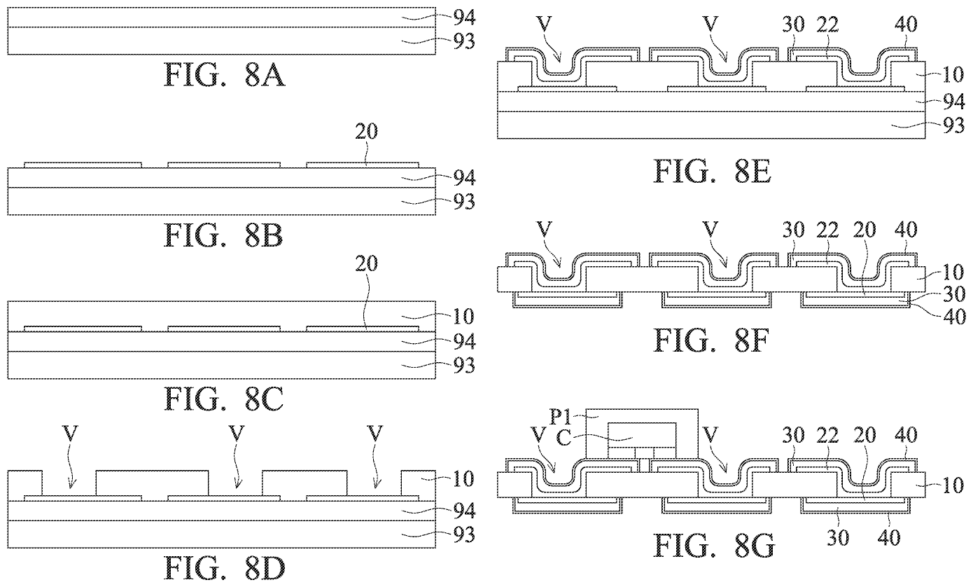

FIG. 8A to FIG. 8G are schematic views of another method for forming a light-emitting device (e.g. the light-emitting device 100) in some embodiments of the present disclosure. In FIG. 8A, a supporting substrate 93 and a sacrificial layer 94 that is disposed on the supporting substrate 93 are provided. The material and function of the supporting substrate 93 may be the same or similar to the supporting substrate 91, and it is not repeated here. The material of the sacrificial layer 94 may include glue, photoresist, amorphous silicon, polymer, another suitable material or a combination thereof, but the present disclosure is not limited thereto.

In FIG. 8B, the conductive layer 20 may be formed on the sacrificial layer 94. In FIG. 8C, the flexible substrate 10 may be provided on the sacrificial layer 94. A layer of suitable material for substrate (e.g. the material of the flexible substrate 10) may be coated on the sacrificial layer 94, and active elements (e.g. the thin-film transistors T) or circuit layer(s) may be disposed in the material for substrate to form the flexible substrate 10, but it is not limited thereto.

In FIG. 8D, vias V may be formed on the flexible substrate 10, and the positions of the vias V may correspond to the conductive layer 20. In FIG. 8E, the conductive layer 22, the barrier layer 30, and the protective layer 40 may be formed on the flexible substrate 10 and the vias V.

In FIG. 8F, the supporting substrate 93 and the sacrificial layer 94 may be removed to expose the conductive layer 20. The supporting substrate 93 and the sacrificial layer 94 may be removed by laser, chemical etching, etc. but it is not limited thereto. In an embodiment, a portion of the flexible substrate 10 may be removed, but it is not limited thereto. Afterwards, the barrier layer 30 and the protective layer 40 may be formed on the conductive layer 20. Finally, in FIG. 8G, the light-emitting unit C may be disposed on the flexible substrate 10 and electrically connected to other elements (not shown) on the flexible substrate 10 through the conductive layer 20, the conductive layer 22, the barrier layer 30, and the protective layer 40 to form the light-emitting device.

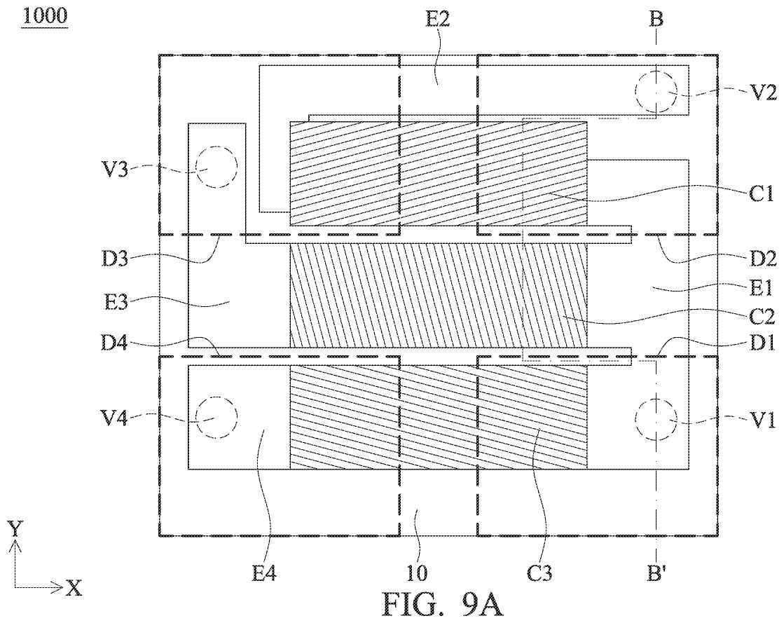

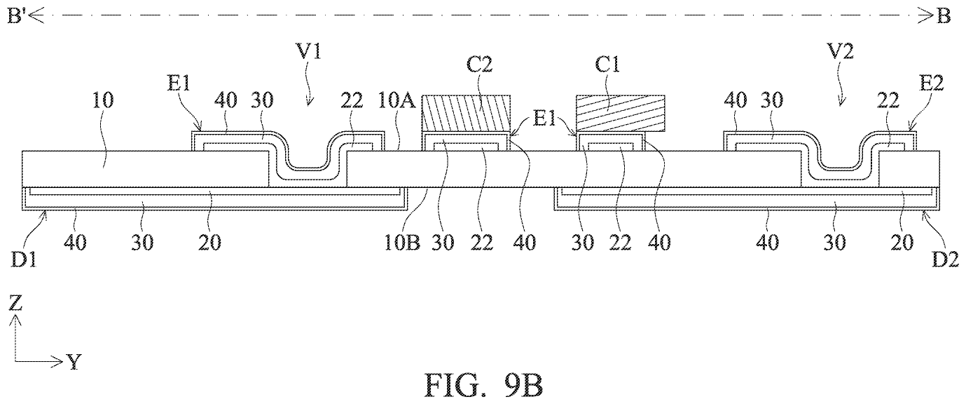

In some embodiments, the light-emitting device may be an LED light-emitting device. For example, FIG. 9A is a top view of a light-emitting device 1000 in some embodiments of the present disclosure, and FIG. 9B is a cross-sectional view of the light-emitting device in FIG. 9A illustrated along the line B-B′. The light-emitting device 1000 may include, for example, a light-emitting unit C1, a light-emitting unit C2, and a light-emitting unit C3. In some embodiments, the color of light emitted from light-emitting unit C1, light-emitting unit C2, and light-emitting unit C3 may be different (such as red, green, blue, yellow) or they may have the same color, but it is not limited thereto. In some embodiments, the substrate may have a high accuracy in the manufacturing processes in the present disclosure. The P-N gap between the anode and the cathode of light-emitting unit C1, light-emitting unit C2, and light-emitting unit C3 may be less than 50 μm to achieve miniaturization.

As shown in FIG. 9A and FIG. 9B, the cathodes or the anodes of light-emitting unit C1, light-emitting unit C2, and light-emitting unit C3 (e.g. the cathodes) may be electrically connected to a conductive structure E1 (including the conductive layer 22, the barrier layer 30, and the protective layer 40) disposed on the top surface 10A of the flexible substrate 10, and may electrically connect to a conductive structure D1 (including the conductive layer 22, the barrier layer 30, and the protective layer 40, shown as a dashed line in FIG. 9A) disposed on the bottom surface 10B of the flexible substrate 10 through a via V1. In other words, the light-emitting unit C1, the light-emitting unit C2, and the light-emitting unit C3 may have a common electrode (cathode or anode). As a result, the number of required electrodes may be reduced. In an embodiment, a portion of the conductive structure E1 may overlap the light-emitting unit C1, the light-emitting unit C2, and the light-emitting unit C3 in the top view.

Other electrodes of the light-emitting unit C1, the light-emitting unit C2, and the light-emitting unit C3 (e.g. anodes) may be respectively connected to the conductive structure E2, the conductive structure E3, the conductive structure E4 (including the conductive layer 22, the barrier layer 30, the protective layer 40) on the top surface 10A of the flexible substrate 10, and then electrically connected to the conductive structure D2, the conductive structure D3, the conductive structure D4 (including the conductive layer 20, the barrier layer 30, the protective layer 40, shown as a dashed line in FIG. 9A) on the bottom surface 10B of the flexible substrate 10. In other words, the cathodes and the anodes of the light-emitting unit C1, the light-emitting unit C2, and the light-emitting unit C3 are electrically separated. In an embodiment, a portion of the conductive structure E2 may overlap the light-emitting unit C1 in the top view. A portion of the conductive structure E3 may overlap the light-emitting unit C2 in the top view. A portion of the conductive structure E4 may overlap the light-emitting unit C3 in the top view. However, the present disclosure is not limited thereto. It is possible that only two of the light-emitting unit C1, the light-emitting unit C2, and the light-emitting unit C3 have a common electrode, or the light-emitting unit C1, the light-emitting unit C2, and the light-emitting unit C3 may not have any common electrode. Therefore, the light-emitting unit C1, the light-emitting unit C2, and the light-emitting unit C3 may be controlled separately.

In summary, a light-emitting device having a substrate with high accuracy is provided in some embodiments of the present disclosure. The accuracy of the substrate is increased, and the size of the substrate may be reduced to achieve miniaturization. It should be noted that the material, the thickness of the material, the profile and structure of the elements, the circuits are only examples, and the size or ranges are only used for illustration, the present is not limited thereto.

The light-emitting device may have touch-control functionality to act as a touch electronic device. Furthermore, the light-emitting device or the touch electronic device in the embodiments of the present disclosure may be applied in any electronic devices with a display screen, such as a display, a mobile phone, a watch, a laptop computer, a video camera, a camera, a mobile navigation device, or a television. These are merely examples, and the applications of the present disclosure are not limited thereto. The aforementioned electronic device may include a display device, an antenna device, a sensing device or a tiled device, a bendable or flexible electronic device, but it is not limited thereto. The light-emitting device of the aforementioned embodiments of the present disclosure may be applied in an electronic device that has an antenna, or in other types of electronic devices. Furthermore, the light-emitting device in aforementioned embodiments may be used as a backlight module of the display device. Since the aforementioned embodiments in the disclosure may perform substantially the same function and obtain substantially the same results, some embodiments of the present disclosure may be combined without conflicting with the spirit of the disclosure.

Although embodiments of the present disclosure and their advantages have been described in detail, it should be understood that various changes, substitutions and alterations may be made herein without departing from the spirit and scope of the disclosure as defined by the appended claims. Moreover, the scope of the present application is not intended to be limited to the particular embodiments of the process, machine, manufacture, and composition of matter, means, methods and steps described in the specification. The features of different embodiments of the present disclosure may be combined, replaced, or rearranged to form another embodiment. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope of such processes, machines, manufacture, and compositions of matter, means, methods, or steps. In addition, each claim constitutes a separate embodiment, and the combination of various claims and embodiments are within the scope of the disclosure.

What is claimed is:

1. A light-emitting device, comprising:
a flexible substrate having a via, a top surface, and a bottom surface;
a light-emitting unit disposed on the top surface of the flexible substrate;
a thin film transistor electrically connected to the light-emitting unit; and
a circuit disposed on the bottom surface of the flexible substrate and transmitting a signal for driving the light-emitting unit through the via.

2. The light-emitting device according to claim 1, wherein the thin film transistor is disposed on the top surface of the flexible substrate.

3. The light-emitting device according to claim 1, wherein the thin film transistor is disposed on the bottom surface of the flexible substrate.

4. The light-emitting device according to claim 1, wherein the circuit comprises a connector.

5. The light-emitting device according to claim 1, wherein the circuit comprises a semiconductor chip.

6. The light-emitting device according to claim 5, further comprising:
a supporting layer; and
a connecting layer disposed between the flexible substrate and the support layer, wherein a thickness of the semiconductor chip is less than a sum of the thicknesses of the support layer and the connecting layer in a normal direction of the flexible substrate.

7. The light-emitting device according to claim 1, further comprising:
a conductive layer disposed in the via; and
a barrier layer covering the conductive layer.

8. The light-emitting device according to claim 7, wherein the conductive layer comprises a material selected from a group consisting of Cu, Ag, Al, Mo, Ti, and a combination thereof.

9. The light-emitting device according to claim 7, wherein the barrier layer comprises a material selected from a group consisting of Ni, Pt, Ag, and a combination thereof.

10. The light-emitting device according to claim 7, further comprising:
another conductive layer electrically connected to the conductive layer and disposed outside the via; and
another barrier layer covering the another conductive layer.

11. The light-emitting device according to claim 7, wherein a thickness of the conductive layer is less than a thickness of the flexible substrate.

12. The light-emitting device according to claim 7, further comprising a protective layer covering the barrier layer, wherein a portion of the protective layer is disposed in the via.

13. The light-emitting device according to claim 12, further comprising a bonding material partially disposed in the via and disposed on the protective layer.

14. The light-emitting device according to claim 1, wherein the via comprises a tapered side wall.

15. The light-emitting device according to claim 14, wherein an angle between the tapered side wall of the via and the bottom surface of the flexible substrate is between 30 degrees and 120 degrees.

16. The light-emitting device according to claim 1, wherein the via is filled with a conductive material.

17. The light-emitting device according to claim 1, wherein the circuit is electrically connected to the thin film transistor and transmits the signal to the thin film transistor.

18. The light-emitting device according to claim 1, further comprising:
another light-emitting unit; and
a package structure, wherein the light-emitting unit and the another light-emitting unit are packaged in the package structure.

19. The light-emitting device according to claim 1, further comprising:
a supporting layer; and
a connecting layer disposed between the flexible substrate and the support layer, wherein a hardness of the support layer is greater than a hardness of the flexible substrate.
